(19) United States
(12) Patent Application Publication
(10) Pub. No.: US 2025/0135473 A1
(43) Pub. Date: May 1, 2025

(54) DUAL CHANNEL SHOWERHEAD CONDUCTANCE OPTIMIZATION FOR UNIFORM RADIAL FLOW DISTRIBUTION

(71) Applicant: Applied Materials, Inc., Santa Clara, CA (US)

(72) Inventors: Barath Kumar, Puducherry (IN); Neela Ayalasomayajula, Bengaluru (IN); Sumesh Suresh, Bangalore (IN); Pratik Pande, Bangalore (IN)

(73) Assignee: Applied Materials, Inc., Santa Clara, CA (US)

(21) Appl. No.: 18/403,247

(22) Filed: Jan. 3, 2024

(30) Foreign Application Priority Data
Oct. 27, 2023 (IN) 202341073254

(51) Int. Cl. B05B 1/18; B05B 1/20; B05B 1/30

(52) U.S. Cl. CPC B05B 1/185; B05B 1/205; B05B 1/30

(57) ABSTRACT

A dual-channel showerhead may include a first plate defining two or more channels and a second plate including a bottom surface and defining a plurality of apertures. Each of the two or more channels may be fluidly coupled with one of the plurality of apertures to define a fluid path extending from the first plate through the bottom surface. The plurality of apertures may be arranged in a series of rings. A first subset of apertures of the plurality of apertures may extend through the first plate and the bottom surface. A second subset of apertures in a first ring of the series of rings may include a first opening area. Each aperture of the second subset in a second ring may include a second opening area smaller than the first opening area, such that a flow conductance of the first ring is within 5% of the second ring.

### CROSS REFERENCE TO RELATED APPLICATION

This application claims the benefit of and priority to Indian Patent Application number 202341073254, entitled “Dual Channel Showerhead Conductance Optimization for Uniform Radial Flow Distribution,” filed on Oct. 27, 2023, the contents of which are hereby incorporated by reference in their entirety.

### FIELD OF INVENTION

The present technology relates to semiconductor processes and equipment. More specifically, the present technology relates to processing system plasma components.

### BACKGROUND

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, many chamber components may include regular patterns of features for providing materials in a way that may increase uniformity. However, this may limit the ability to tune recipes for on-wafer adjustments.

Thus, there is a need for improved systems and methods that can be used to produce high quality devices and structures. These and other needs are addressed by the present technology.

### BRIEF SUMMARY

A dual-channel showerhead may include a first plate defining two or more channels. The showerhead may include a second plate may include a bottom surface and defining a plurality of apertures. Each of the two or more channels is fluidly coupled with at least one of the plurality of apertures to define a fluid path extending from the first plate of the showerhead through the bottom surface of the showerhead. The plurality of apertures may be arranged in a series of concentric rings about a center of the bottom surface. A first subset of apertures of the plurality of apertures may extend through the first plate and the bottom surface. A second subset of apertures of the plurality of apertures, in a first concentric ring of the series of concentric rings may include a first opening area. Each aperture of the second subset of apertures in a second concentric ring may include a second opening area smaller than the first opening area, such that a flow conductance of the first concentric ring is within 5% of the second concentric ring, and where the second concentric ring is radially outward of the first concentric ring.

In some embodiments, each ring within the series of concentric rings may be arranged substantially hexagonally. Each ring within the series of concentric rings may be arranged substantially annularly. The first plate may define a recess and the second plate may be disposed within the recess. A gas inlet may include an opening formed on a lateral surface of the first plate. The second plate may define a plenum that fluidly couples the gas inlet with each aperture of the second subset of apertures. A total opening area of the second subset of apertures may be substantially equal to an area of an inlet. A diameter of each aperture of the second subset of apertures may decrease as a distance from the center of the bottom surface increases. A diameter of each of the second subset of apertures may be within a range of 10 mm to 40 mm, inclusive. A total opening area of each concentric ring of apertures may be defined by a total of the opening areas of each of the second subset of apertures within the respective concentric ring, where the total opening area of each respective concentric ring is substantially equal. Each of the first subset of apertures and each of the second subset of apertures may be generally cylindrical. Each aperture of the plurality of apertures may include a square shape.

semiconductor processing system may include a processing chamber and a dual-channel showerhead within the processing chamber. The dual-channel showerhead may include a second plate may include a bottom surface and defining a plurality of apertures. Each of the two or more channels is fluidly coupled with at least one of the plurality of apertures to define a fluid path extending from the first plate of the showerhead through the bottom surface of the showerhead. The plurality of apertures may be arranged in a series of concentric rings about a center of the bottom surface. A first subset of apertures of the plurality of apertures may extend through the first plate and the bottom surface. A second subset of apertures of the plurality of apertures, in a first concentric ring of the series of concentric rings may include a first opening area. Each aperture of the second subset of apertures in a second concentric ring may include a second opening area smaller than the first opening area, such that a flow conductance of the first concentric ring is within 5% of the second concentric ring, and where the second concentric ring is radially outward of the first concentric ring.

A method of processing a substrate may include providing a first gas into a processing chamber through a first subset of apertures of a showerhead. The method may include providing a second gas into the processing chamber through a second subset of apertures of the showerhead, the second subset of apertures being fluidly connected to a gas inlet via at least one of a channel or a plenum formed in the showerhead. A flow conductance of the gas inlet is the same as the flow conductance of the second subset of apertures. The method may include depositing a material on a substrate positioned within the processing chamber.

In some embodiments, the first gas may include oxygen and the second gas may include bis(diethylamino)silane. A saturation of at least the second gas in the processing chamber may be reached within a range of 0.1 to 0.4 seconds, inclusive. A radial uniformity associated with the saturation may be reached within a range of 0.1 to 0.4 seconds, inclusive. A diameter of each of the second subset of apertures may be within a range of 10 mm to 60 mm, inclusive. Each of the first subset of apertures may be fluidly connected to a first gas line.

### BRIEF DESCRIPTION OF THE DRAWINGS

FIG. 1 shows a top plan view of one embodiment of a processing tool of deposition, etching, baking, and/or curing chambers, according to certain embodiments.

FIG. 2A illustrates a cross-sectional view of an exemplary process chamber section with partitioned plasma generation regions within the processing chambers, according to certain embodiments.

FIG. 2B illustrates a side schematic view of the precursor flow processes in the processing chambers and the gas distribution assemblies, according to certain embodiments.

FIG. 2C is a side schematic view of the precursor flow processes in the processing chambers and the gas distribution assemblies, according to certain embodiments.

FIG. 3A illustrates an upper perspective view of a dual-channel showerhead, according to certain embodiments.

FIG. 3B illustrates an exploded perspective view of a dual-channel showerhead, according to certain embodiments.

FIG. 3C illustrates a cross-sectional side elevation view of a dual-channel showerhead, according to certain embodiments.

FIG. 3D illustrates a cross-sectional top plan view of gas channel configurations of the dual-channel showerhead, according to certain embodiments.

FIG. 3E illustrates a cross-sectional top plan view of gas channel configurations of the dual-channel showerhead, according to certain embodiments.

FIG. 4A illustrates a simplified bottom-side view of a dual-channel showerhead with multiple zones, according to certain embodiments.

FIG. 4B illustrates a cross sectional view of a portion of the dual-channel showerhead 400, according to certain embodiments.

FIG. 5 illustrates a dual-channel showerhead including apertures arranged in annular concentric rings, according to certain embodiments.

FIG. 6 illustrates a dual-channel showerhead including apertures arranged in octagonal concentric rings, according to certain embodiments.

FIG. 7 illustrates a flowchart of a method for processing a substrate, according to certain embodiments.

FIG. 8 illustrates a flowchart of a method 800 for optimizing flow conductance through a dual-channel showerhead, according to certain embodiments.

### DETAILED DESCRIPTION

Atomic Layer Deposition (ALD) is one process commonly used in semiconductor fabrication. Using ALD, one or more precursors may be applied to a substrate within a processing chamber, resulting in layers (or films) of a material being deposited on the substrate. The substrate may include many dies, with each die being made into an identical semiconductor device by layering materials on the substrate during the semiconductor fabrication process. To form a particular layer on the substrate, the precursor may be provided to the processing chamber. As the processing chamber fills with the precursor, material is deposited on the substrate. Once the substrate has reached saturation, no more material may be deposited on the substrate, and the particular layer may be formed. Because the substrate may include many dies, variation in the concentration or delivery of the precursor within the processing chambers may lead to non-uniformity of the semiconductors produced on the substrate.

Flow conductance is a measure of a rate at which a fluid may pass through a region and is dependent on the area through which the fluid travels. The rate at which the precursor may be delivered to the processing chamber may therefore depend partially on the flow conductance of the components within the processing chamber. For example, a showerhead may be used provide the precursor to the processing chamber. The showerhead may include several apertures to deliver the precursor, arranged in concentric rings about a center of the showerhead. Rings nearest the center of the showerhead may include fewer apertures than the rings further from the center, thus having less total opening area and a lower flow conductance. A region of the substrate near the center of the showerhead may therefore be exposed to the precursor at a slower rate, reaching the saturation point slower than a region further from the center. The resulting semiconductor devices may be non-uniform, with variations based on each device's location on the substrate. Thus, it may be beneficial to provide a more uniform delivery of the precursor to all areas of the substrate.

In some systems and processing chambers, it may not be practical to increase the flow the precursor to the showerhead. Therefore, the flow conductance from the showerhead may be altered in order to provide the precursor more uniformly to the processing chamber. One approach may be to increase the number of apertures in the inner rings. However, current showerhead designs may already maximize the number of apertures a showerhead can include due to space limitations within the inner region. Another approach may be to decrease the number of apertures in outer rings, but this would slow down the semiconductor fabrication process by reducing the overall flow conductance of the showerhead.

Another solution may be to optimize the diameter of the apertures such that the flow conductance of all regions of the showerhead is substantially equal. For example, a showerhead may be divided into one or more zones about a center of the showerhead. The zones may each include a subset of apertures. Then, the diameter of the apertures within each zone may be adjusted such that the flow conductance of each zone is similar. For example, because zones closer to the edge of the showerhead may include more apertures than zones nearer the center, the diameter of the apertures in the outer zones may be smaller than those in zones nearer the center. The diameters may be configured such that a flow conductance of each zone is substantially similar. Because the flow conductance of each zone is substantially similar, deposition on a substrate may be more even.

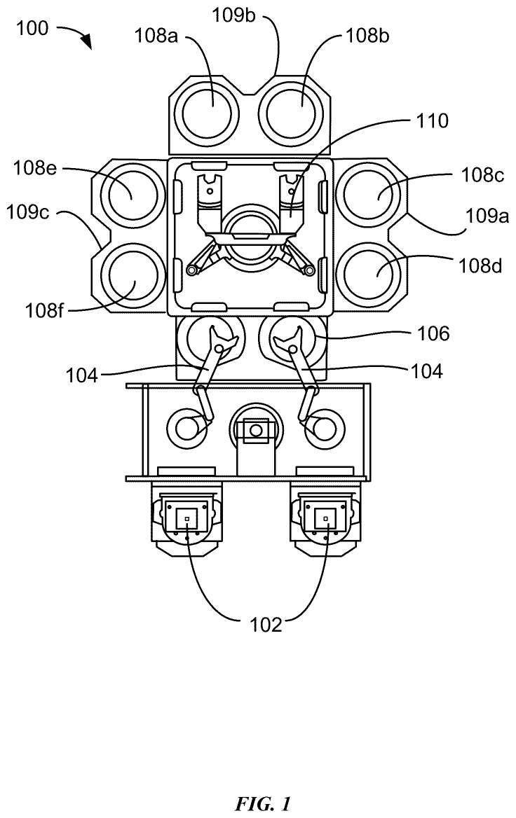

FIG. 1 shows a top plan view of one embodiment of a processing tool 100 of deposition, etching, baking, and/or curing chambers according to disclosed embodiments. In the figure, a pair of FOUPs (front opening unified pods) 102 supply substrates (e.g., various specified diameter semiconductor wafers) that may be received by robotic arms 104 and placed into a low-pressure holding area 106 before being placed into one of the substrate processing sections 108a-f of the tandem process chambers 109a-c. A second robotic arm 110 may be used to transport the substrates from the holding area 106 to the processing chambers 108a-f and back.

The substrate processing sections 108a-f of the tandem process chambers 109a-c may include one or more system components for depositing, annealing, curing and/or etching substrates or films thereon. Exemplary films may be flowable dielectrics, but many types of films may be formed or processed with the processing tool. In one configuration, two pairs of the tandem processing sections of the processing chamber (e.g., 108c-d and 108e-f) may be used to deposit the dielectric material on the substrate, and the third pair of tandem processing sections (e.g., 108a-b) may be used to anneal the deposited dielectric. In another configuration, the two pairs of the tandem processing sections of processing chambers (e.g., 108c-d and 108e-f) may be configured to both deposit and anneal a dielectric film on the substrate, while the third pair of tandem processing sections (e.g., 108a-b) may be used for UV or E-beam curing of the deposited film. In still another configuration, all three pairs of tandem processing sections (e.g., 108a-f) may be configured to deposit and cure a dielectric film on the substrate or etch features into a deposited film.

In yet another configuration, two pairs of tandem processing sections (e.g., 108c-d and 108e-f) may be used for both deposition and UV or E-beam curing of the dielectric, while a third pair of tandem processing sections (e.g., 108a-b) may be used for annealing the dielectric film. In addition, one or more of the tandem processing sections 108a-f may be configured as a treatment chamber and may be a wet or dry treatment chamber. These process chambers may include heating the dielectric film in an atmosphere that includes moisture. Thus, embodiments of system 100 may include wet treatment tandem processing sections 108a-b and anneal tandem processing sections 108c-d to perform both wet and dry anneals on the deposited dielectric film. It will be appreciated that additional configurations of deposition, annealing, and curing chambers for dielectric films are contemplated by system 100.

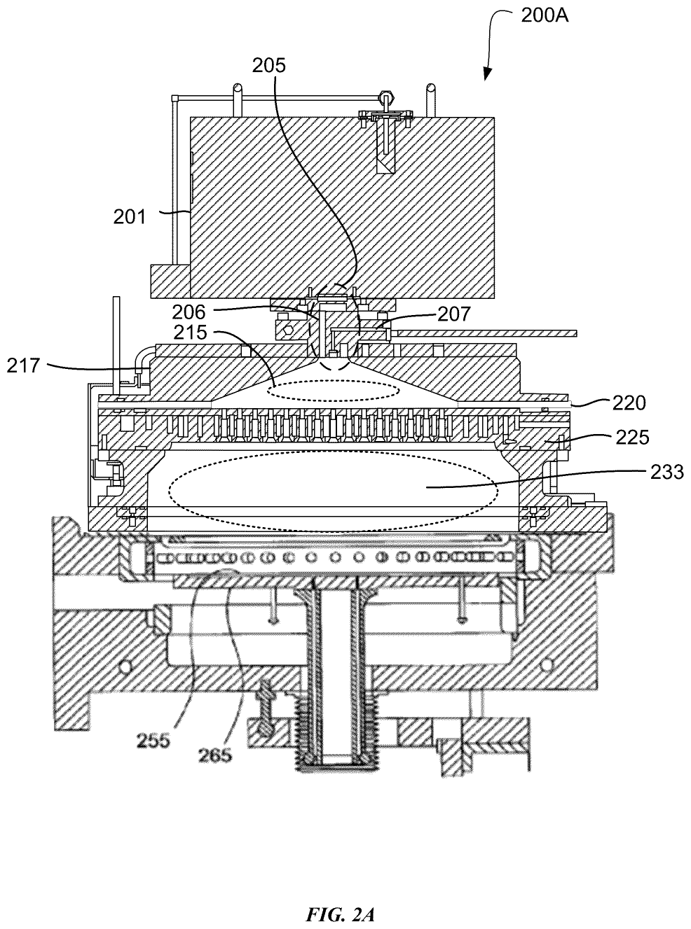

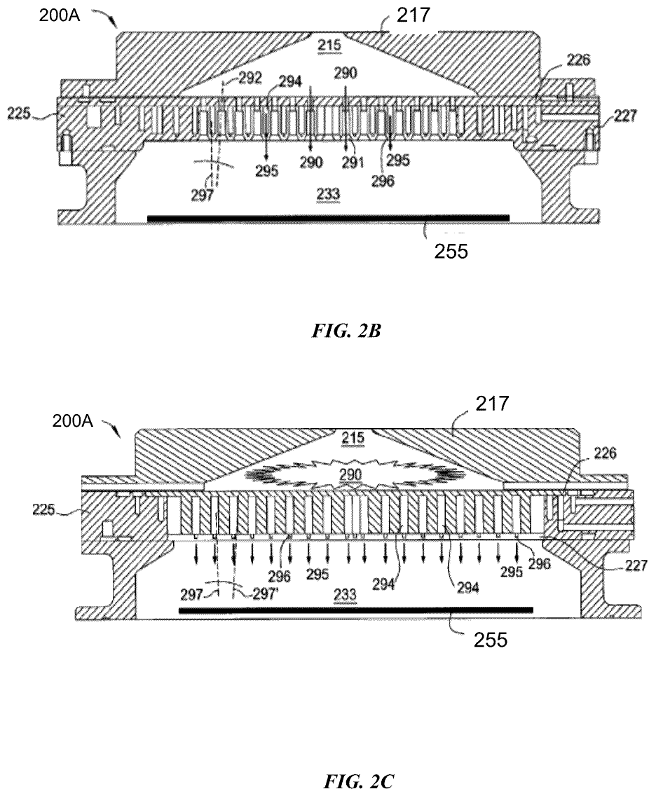

FIG. 2A is a cross-sectional view of an exemplary process chamber section 200 with partitioned plasma generation regions within the processing chambers. During film deposition (e.g., silicon oxide, silicon nitride, silicon oxynitride, or silicon oxycarbide), a process gas may be flowed into the first plasma region 215 through a gas inlet assembly 205. The gas inlet assembly 205 may be disposed on a lateral surface of a showerhead 225 and/or the process chamber 200. A remote plasma system (RPS) 201 may process a gas which then travels through gas inlet assembly 205. Two distinct gas supply channels are visible within the gas inlet assembly 205. A first channel 206 carries a gas that passes through the remote plasma system (RPS) 201, while a second channel 207 bypasses the RPS 201. The first channel 206 may be used for the process gas and the second channel 207 may be used for a treatment gas in disclosed embodiments. The process gas may be excited prior to entering the first plasma region 215 within a remote plasma system (RPS) 201. A lid 212, a showerhead 225, and a substrate support 265, having a substrate 255 disposed thereon, are shown according to disclosed embodiments. The lid 212 may be pyramidal, conical, or of another similar structure with a narrow top portion expanding to a wide bottom portion. Additional geometries of the lid 212 may also be used. The lid (or conductive top portion) 212 and showerhead 225 are shown with an insulating ring 220 in between, which allows an AC potential to be applied to the lid 212 relative to showerhead 225. The insulating ring 220 may be positioned between the lid 212 and the showerhead 225 enabling a capacitively coupled plasma (CCP) to be formed in the first plasma region. A baffle (not shown) may additionally be located in the first plasma region 215 to affect the flow of fluid into the region through gas inlet assembly 205.

A fluid, such as a precursor, for example a silicon-containing precursor, may be flowed into the processing region 233 by embodiments of the showerhead described herein. Excited species derived from the process gas in the plasma region 215 may travel through apertures in the showerhead 225 and react with the precursor flowing into the processing region 233 from the showerhead. Little or no plasma may be present in the processing region 233. Excited derivatives of the process gas and the precursor may combine in the region above the substrate and, on occasion, on the substrate to form a film on the substrate that may be flowable in disclosed applications. For flowable films, as the film grows, more recently added material may possess a higher mobility than underlying material. Mobility may decrease as organic content is reduced by evaporation. Gaps may be filled by the flowable film using this technique without leaving traditional densities of organic content within the film after deposition is completed. A curing step may still be used to further reduce or remove the organic content from a deposited film.

Exciting the process gas in the first plasma region 215 directly, exciting the process gas in the RPS, or both, may provide several benefits. The concentration of the excited species derived from the process gas may be increased within the processing region 233 due to the plasma in the first plasma region 215. This increase may result from the location of the plasma in the first plasma region 215. The processing region 233 may be located closer to the first plasma region 215 than the remote plasma system (RPS) 201, leaving less time for the excited species to leave excited states through collisions with other gas molecules, walls of the chamber, and surfaces of the showerhead.

The uniformity of the concentration of the excited species derived from the process gas may also be increased within the processing region 233. This may result from the shape of the first plasma region 215, which may be more similar to the shape of the processing region 233. Excited species created in the remote plasma system (RPS) 201 may travel greater distances in order to pass through apertures near the edges of the showerhead 225 relative to species that pass through apertures near the center of the showerhead 225. The greater distance may result in a reduced excitation of the excited species and, for example, may result in a slower growth rate near the edge of a substrate. Exciting the process gas in the first plasma region 215 may mitigate this variation.

The processing gas may be excited in the RPS 201 and may be passed through the showerhead 225 to the processing region 233 in the excited state. Alternatively, power may be applied to the first processing region to either excite a plasma gas or enhance an already exited process gas from the RPS. While a plasma may be generated in the processing region 233, a plasma may alternatively not be generated in the processing region. In one example, the only excitation of the processing gas or precursors may be from exciting the processing gas in the RPS 201 to react with the precursors in the processing region 233.

The processing chamber and this discussed tool are more fully described in patent application Ser. No. 12/210,940 filed on Sep. 15, 2008, and patent application Ser. No. 12/210,982 filed on Sep. 15, 2008, which are incorporated herein by reference to the extent not inconsistent with the claimed aspects and description herein.

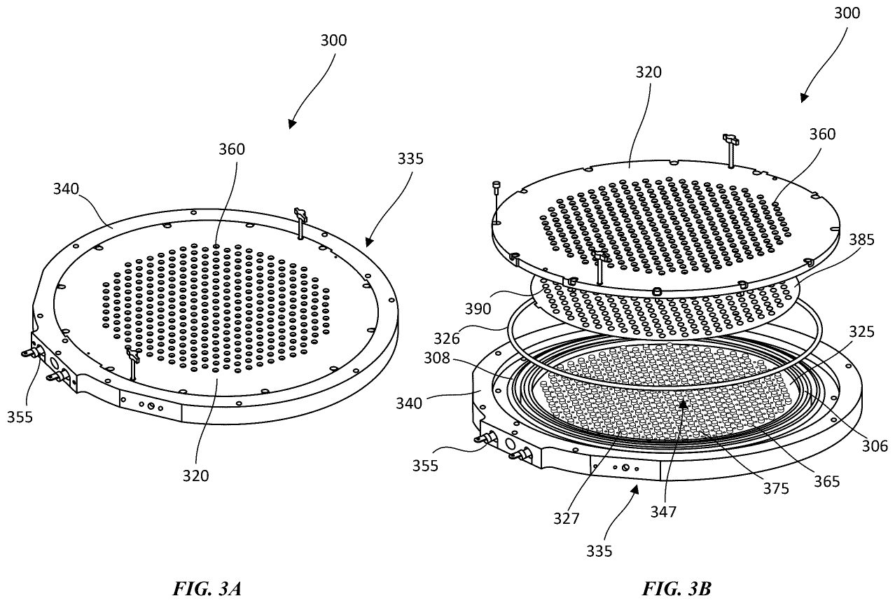

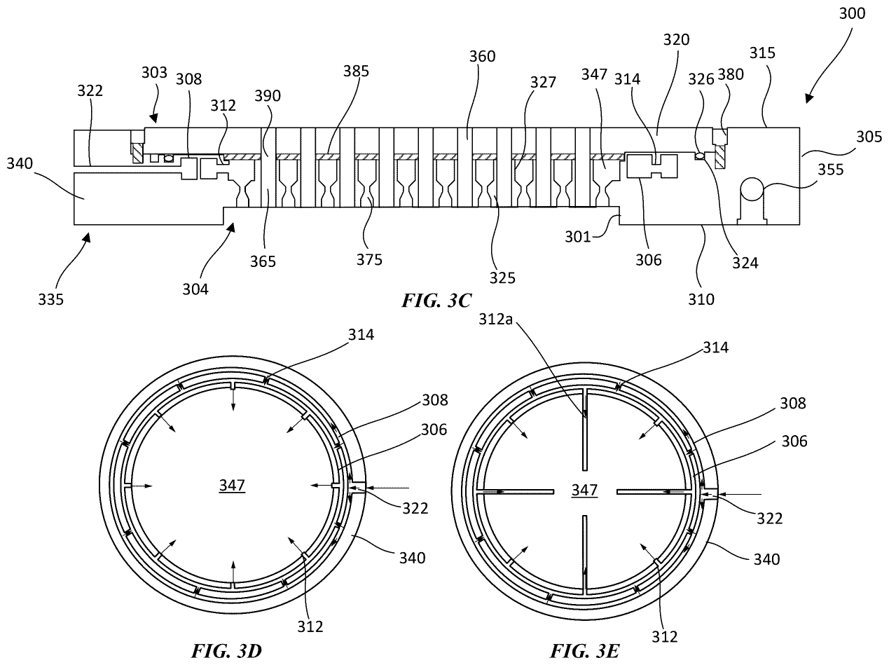

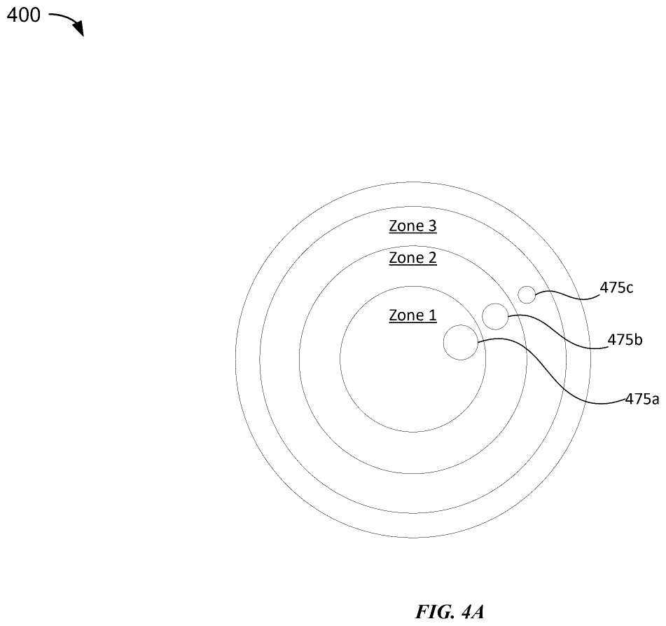

FIGS. 2B-2C are side schematic views of one embodiment of the precursor flow processes in the processing chambers and the gas distribution assemblies described herein. The gas distribution assemblies for use in the processing chamber section 200 may be referred to as dual-channel showerheads (DCSH) or triple channel showerheads (TCSH) and are detailed in the embodiments described in FIGS. 3A-3E, 4, 5, 6, 7, 8A, 8B, and 9 herein. The dual or triple channel showerhead may allow for flowable deposition of a dielectric material, and separation of precursor and processing fluids during operation. The showerhead may alternatively be utilized for etching processes that allow for separation of etchants outside of the reaction zone to provide limited interaction with chamber components.

Precursors may be introduced into the distribution zone by first being introduced into an internal showerhead volume 294 defined in the showerhead 225 by a first manifold 226, or upper plate, and second manifold 227, or lower plate. The manifolds may be perforated plates that define a plurality of apertures. The precursors in the internal showerhead volume 294 may flow 295 into the processing region 233 via apertures 296 formed in the lower plate. This flow path may be isolated from the rest of the process gases in the chamber, and may provide for the precursors to be in an unreacted or substantially unreacted state until entry into the processing region 233 defined between the substrate 255 and a bottom of the lower plate 227. Once in the processing region 233, the precursor may react with a processing gas. The precursor may be introduced into the internal showerhead volume 294 defined in the showerhead 225 through a side channel formed in the showerhead, such as gas inlets 322, 422, 522, 622, 722, 822, 922 as shown in the showerhead embodiments herein. The process gas may be in a plasma state including radicals from the RPS unit or from a plasma generated in the first plasma region. Additionally, a plasma may be generated in the processing region.

Processing gases may be provided into the first plasma region 215, or upper volume, defined by the faceplate 217 and the top of the showerhead 225. The processing gas may be plasma excited in the first plasma region 215 to produce process gas plasma and radicals. Alternatively, the processing gas may already be in a plasma state after passing through a remote plasma system prior to introduction to the first plasma processing region 215 defined by the faceplate 217 and the top of the showerhead 225.

The processing gas including plasma and radicals may then be delivered to the processing region 233 for reaction with the precursors though channels, such as channels 290, formed through the apertures in the showerhead plates or manifolds. Channels 290 and apertures 291 may form a fluid path, through which a gas may be provided. The processing gasses passing though the channels may be fluidly isolated from the internal showerhead volume 294 and may not react with the precursors passing through the internal showerhead volume 294 as both the processing gas and the precursors pass through the showerhead 225. Once in the processing volume, the processing gas and precursors may mix and react.

In addition to the process gas and a dielectric material precursor, there may be other gases introduced at varied times for varied purposes. A treatment gas may be introduced to remove unwanted species from the chamber walls, the substrate, the deposited film and/or the film during deposition. A treatment gas may be excited in a plasma and then used to reduce or remove residual content inside the chamber. In other disclosed embodiments the treatment gas may be used without a plasma. When the treatment gas includes water vapor, the delivery may be achieved using a mass flow meter (MFM), an injection valve, or by commercially available water vapor generators. The treatment gas may be introduced from the first processing region, either through the RPS unit or bypassing the RPS unit, and may further be excited in the first plasma region.

The axis 292 of the opening of apertures 291 and the axis 297 of the opening of apertures 296 may be parallel or substantially parallel to one another. Alternatively, the axis 292 and axis 297 may be angled from each other, such as from about 1° to about 80°, for example, from about 1° to about 30°. Alternatively, each of the respective axes 292 may be angled from each other, such as from about 1° to about 80°, for example, from about 1° to about 30°, and each of the respective axis 297 may be angled from each other, such as from about 1° to about 80°, for example, from about 1° to about 30°.

The respective openings may be angled, such as shown for aperture 291 in FIG. 2B, with the opening having an angle from about 1° to about 80°, such as from about 1° to about 30°. The axis 292 of the opening of apertures 291 and the axis 297 of the opening of apertures 296 may be perpendicular or substantially perpendicular to the surface of the substrate 255. Alternatively, the axis 292 and axis 297 may be angled from the substrate surface, such as less than about 5°.

FIG. 2C illustrates a partial schematic view of the processing chamber 200 and showerhead 225 illustrating the precursor flow 295 from the internal volume 294 through apertures 296 into the processing region 233. The figure also illustrates an alternative embodiment showing axis 297 and 297′ of two apertures 296 being angled from one another.

FIG. 3A illustrates an upper perspective view of a dual-channel showerhead 300. FIG. 3A may include one or more components discussed above with regard to FIG. 2A, and may illustrate further details relating to that chamber. The dual-channel showerhead 300 may be used to perform semiconductor processing operations including deposition of stacks of dielectric materials and/or etching operations as previously described. Dual-channel showerhead 300 may be used in semiconductor processing chambers, such as chamber 200 described above, and may not include all of the components, such as additional lid stack components previously described, which are understood to be incorporated in some embodiments of dual-channel showerhead 300. In usage, the dual-channel showerhead 300 may have a substantially horizontal orientation such that an axis of the gas apertures formed therethrough may be perpendicular or substantially perpendicular to the plane of the substrate support (see substrate support 265 in FIG. 2A). FIG. 3B illustrates an exploded perspective view of the dual-channel showerhead 300. FIG. 3C is a cross-sectional side elevation view of the dual-channel showerhead 300. FIGS. 3D and 3E illustrate cross-sectional top plan views of gas channel configurations of the dual-channel showerhead 300.

Referring to FIGS. 3A-3E, the dual-channel showerhead 300 generally includes a base 335 having an annular body 340, an upper plate 320, and a lower plate 325. In some embodiments, the lower plate 325 may be formed integrally with the annular body 340, while in other embodiments the lower plate 325 may be a separate component. The annular body 340 may be a ring which has an inner annular wall 301 located at an inner diameter, an outer annular wall 305 located at an outer diameter, an upper surface 315, and a lower surface 310. The upper surface 315 and lower surface 310 define the thickness of the annular body 340. A conduit or annular temperature channel or recess may be defined within the annular body 340 and may be configured to receive a cooling fluid or a heating element that may be used to maintain or regulate the temperature of the annular body. For example, as illustrated in FIG. 3C, a conduit may be formed in the bottom surface 310 and a heating element 355 may be disposed therein. The heating element 355 and/or cooling channel may extend about all or substantially all of the annular body 340.

One or more recesses and/or channels may be formed in or defined by the annular body as shown in disclosed embodiments including that illustrated in FIG. 3D. The annular body may include an upper recess 303 formed in the upper surface. The upper recess 303 may be a upper recess formed in the annular body 340. As shown in FIGS. 3B and 3C, a first fluid channel 306 may be defined in the upper surface 315, and may be located in the annular body radially inward of the upper recess 303. The first fluid channel 306 may be annular in shape and be formed the entire distance around the annular body 340. In disclosed embodiments, a bottom portion of the upper recess 303 intersects an outer wall of the first fluid channel 306. As best illustrated in FIGS. 3D and 3E, a number of ports 312 may be defined in an inner wall of the first fluid channel, also the inner annular wall 301 of the annular body 340. The ports 312 may provide access between the first fluid channel and the internal volume defined between the upper plate 320 and lower plate 325. The ports 312 may be defined around the circumference of the channel 306 at specific intervals, and may facilitate distribution across the entire region of the volume defined between the upper and lower plates, which may form a plenum 347. The intervals of spacing between the ports 312 may be constant, or may be varied in different locations to affect the flow of fluid into the volume. In some embodiments, a length of each port 312 may be constant, such as shown in FIG. 3D. In other embodiments, one or more of the ports 312a may extend a greater distance into an interior of the plenum 347. For example, as illustrated in FIG. 3E four (of eight) equally spaced apart ports 312a may extend further into a center of the plenum 347 (such as beyond 30% of the radius of the channel 306, beyond or about 40% of the radius, beyond or about 50% of the radius, beyond or about 60% of the radius, beyond or about 70% of the radius, beyond or about 80% of the radius, or more) than the remaining ports 312. It will be appreciated that any number and/or configuration of ports may be utilized to achieve a desired gas distribution within the plenum 347. The inner and outer walls, radially, of the first fluid channel 306 may be of similar or dissimilar height. For example, the inner wall may be formed higher than the outer wall to affect the distribution of fluids in the first fluid channel to avoid or substantially avoid the flow of fluid over the inner wall of the first fluid channel.

Again referring to FIGS. 3B and 3C, a second fluid channel 308 may be defined in the upper surface 315 that is located in the annular body radially outward of the first fluid channel 306. Second fluid channel 308 may be an annular shape and be located radially outward from and concentric with first fluid channel 306. The second fluid channel 308 may also be located radially outward of the first upper recess 303. A second plurality of ports 314 may be defined in the portion of the annular body 340 defining the outer wall of the first fluid channel 306 and the inner wall of the second fluid channel 308. The second plurality of ports 314 may be located at intervals of a pre-defined distance around the channel to provide fluid access to the first fluid channel 306 at several locations about the second fluid channel 308. In operation, a precursor may be flowed from outside the process chamber to a delivery channel or gas inlet 322 located in the side of the annular body 340. The precursor may include Bis(diethylamino)silane (BDEAS) or other suitable precursor, and/or a neutral gas (e.g., argon). The fluid may flow into the second fluid channel 308, through the second plurality of ports 314 into the first fluid channel 306, through the first plurality of ports 312 into the plenum 347 defined between the upper and lower plates, and through third apertures 375 located in the lower plate. As such, a fluid provided in such a fashion can be isolated or substantially isolated from any fluid delivered into the first plasma region through first apertures 360 (formed in the upper plate 320) and second apertures 365 (formed in the lower plate 325) until the fluids separately exit the lower plate 325. The fluid channels and fluid ports may together define a recursive flow path that that fluidly couples the gas inlet 322 with the plenum 347 to uniformly distribute the fluid within the plenum 347.

The upper plate 320 may be a disk-shaped body, and may be coupled with the annular body 340 at the first upper recess 303 or other seat. The upper plate 320 may thus cover the first fluid channel 306 to prevent or substantially prevent fluid flow from the top of the first fluid channel 306. The upper plate may have a diameter selected to mate with the diameter of the upper recess 303, and the upper plate may include a plurality of first apertures 360 formed therethrough. As seen in FIG. 3A, the first apertures 360 may be arranged in a polygonal pattern on the upper plate 320, such that an imaginary line drawn through the centers of the outermost first apertures 360 define or substantially define a polygonal figure, which may be for example, a six-sided polygon.

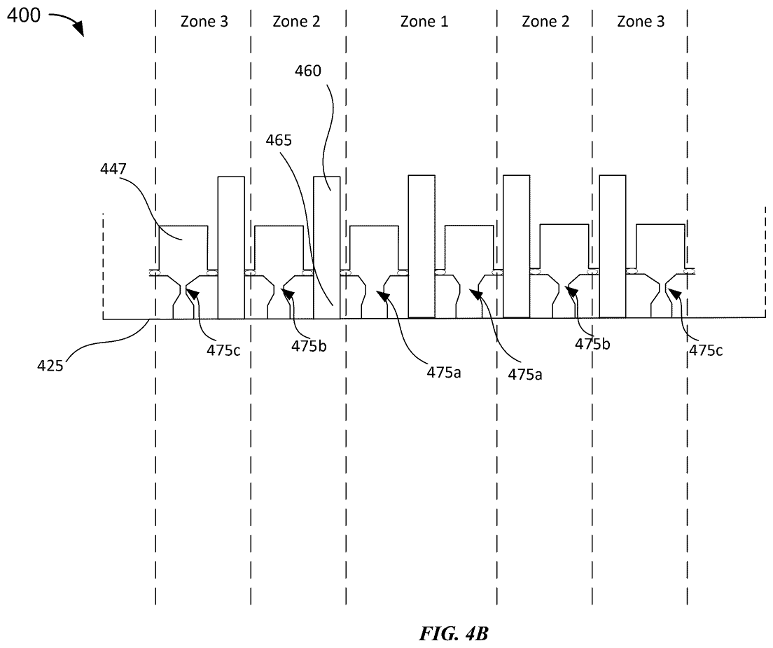

FIG. 4A illustrates a simplified bottom-side view of a dual-channel showerhead 400 with multiple zones, according to certain embodiments. FIG. 4B illustrates a cross sectional view of a portion of the dual-channel showerhead 400, according to certain embodiments. The dual-channel showerhead 400 may include any of the features or characteristics of dual-channel showerhead 300 and may be incorporated in any chamber in which a dual-channel showerhead may be used, including any chamber previously described. For example, the dual-channel showerhead 400 may include an upper plate (not shown) defining a number of first apertures 460 (similar to the first apertures 360) and a lower plate 425 that defines second apertures 465 that are aligned with first apertures. Lower plate 425 may also define third apertures 475a-c that are fluidly isolated from the first apertures and second apertures. For example, the third apertures 475 may be fluidly coupled with a gas inlet via one or more channels and/or a plenum. The portion of the dual-channel showerhead 400 shown in FIG. 4B may only include the first apertures 460, the second apertures 465, and the third apertures 475. It will be appreciated that other components described above may be present even if not illustrated in FIG. 4B.

The dual-channel showerhead 400 may be divided into multiple zones. While FIGS. 4A and B illustrate three zones, any number of zones may be present (e.g., 5, 10, 15). Each zone may include one or more rows or rings of apertures, and in some embodiments each row or ring of apertures may be a distinct zone. Although only one third aperture 475a-c is shown in each of zones 1-3 In FIG. 4A, it should be understood that there may be any number of third apertures 475a-c in any of the zones 1-3. Within each of the multiple zones, the third apertures 475a-c may be defined by a diameter. For example, all of the third apertures 475a in zone 1 may include a first diameter. The third apertures 475b in zone 2 may include a second diameter, smaller than the first diameter. The third apertures 475c in zone 3 may include a third diameter, smaller than the second diameter.

During operation, the third apertures may deliver a precursor (such as the precursor described in FIGS. 3B and 3C) to the processing chamber. The third apertures 475a-c may be configured such that a total opening area of the third apertures within each of the zones 1-3 are substantially equal (e.g., within 5%). For example, a sum of the cross-sectional areas of all apertures within each zone may be equal. For example, zones with greater numbers of apertures may include apertures with smaller diameters than zones with smaller numbers of apertures. The cross-sectional area of any aperture may be defined by a smallest diameter of the aperture.

As each of the zones 1-3 may include a substantially equal total opening area, each of the zones 1-3 may therefore have an identical flow conductance. Because zones 1-3 have an identical flow conductance, all regions of a substrate within the processing chamber may reach the saturation point at or near the same time. In other words, by varying the diameter of the third apertures 475a-c across different zones of the dual-channel showerhead 400, a substantially equal amount of precursor may be delivered to the various regions of the substrate in the processing chamber. Thus, the uniformity of semiconductors fabricated on the substrate may be increased. In some embodiments, the total flow conductance of the third apertures 475a-c may be the same flow conductance as that of the gas inlet.

Furthermore, by adjusting the diameter of the third apertures 475a-c, the total time needed for all regions of the substrate to reach saturation may be reduced. For example, a mole fraction of the precursor may need to reach a certain level within the processing chamber in order for deposition to occur (e.g., 0.015). By adjusting the diameter of apertures according to the systems and methods herein, the time taken for all regions of the substrate to reach the certain level may be within a range of 0.1 to 0.4 seconds, inclusive. Thus, the semiconductor fabrication process may be completed in less time than using conventional systems and processes.

In FIG. 4B, the third apertures 475a-c are shown as having aperture profiles that begin with conical portions that narrow the third apertures 475a-c between the plenum 447 and the lower plate 425. The aperture profile then widens again as the aperture reaches a bottom surface of the lower plate 425. In other embodiments, the third apertures 475a-c may have a constant diameter or may vary in a different manner. The narrow region of each third aperture 475a-c may control the flow conductance through the aperture. The third apertures may also include one or more horizontal walls extending from the lateral sides towards the center of the third apertures 475a-c, such that the constant diameter is narrowed by a gap between the horizontal walls. Alternatively, the constant diameter of each of the third apertures may vary, corresponding to the constant diameter of other third apertures 475a-c in the same zone 1-3. In yet another embodiment, an opening in the lower plate 435 of each of the third apertures 475a-c may vary according to the zone 1-3. In other embodiments, all openings may be identical, with the relevant diameter defined as an internal diameter (as shown in FIG. 4B). In any embodiment, the diameter of the third apertures 475a-c may be the narrowest portion of the third apertures 475a-c. The third apertures 475a-c may also be substantially round, square, or any other suitable shape. In some embodiments, the first apertures 460 and second apertures 465 may include a uniform diameter, as shown in FIG. 4B. In other embodiments, the first apertures 460 and second apertures 465 may also vary, similar to the third apertures 475a-c.

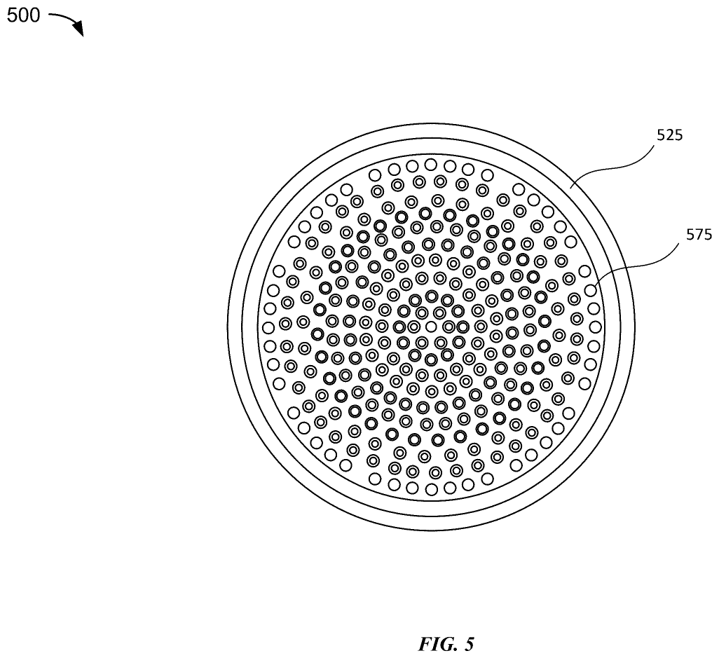

FIG. 5 illustrates a dual-channel showerhead 500 including apertures 575 arranged in annular concentric rings, according to certain embodiments. The dual-channel showerhead 500 may include any of the features or characteristics of dual-channel showerheads 300 or 400 and may be incorporated in any chamber in which a dual-channel showerhead may be used, including any chamber previously described. The dual-channel showerhead may include a lower plate 525. The apertures 575 may be arranged in annular concentric rings about a center of the dual-channel showerhead 500. Any number of annular concentric rings may be present (e.g., 10, 15, 20, etc.). Each of annular concentric rings may be included in a zone. Each zone may include one or more of the annular concentric rings. Each zone may be defined, at least in part, by a diameter of the apertures 575 included in each zone. For example, the apertures included in a zone nearer the center may include a diameter larger than those farther from the center, as is described in relation to FIGS. 4A and 4B. The use of a greater number of zones (e.g., a smaller number of rings within each zone) may provide a greater level of granularity that leads to more uniform flow of gas through the surface of the faceplate. Thus, in some embodiments it may be beneficial to design a faceplate to have each ring of apertures define a single zone, which may provide a particularly high level of flow uniformity.

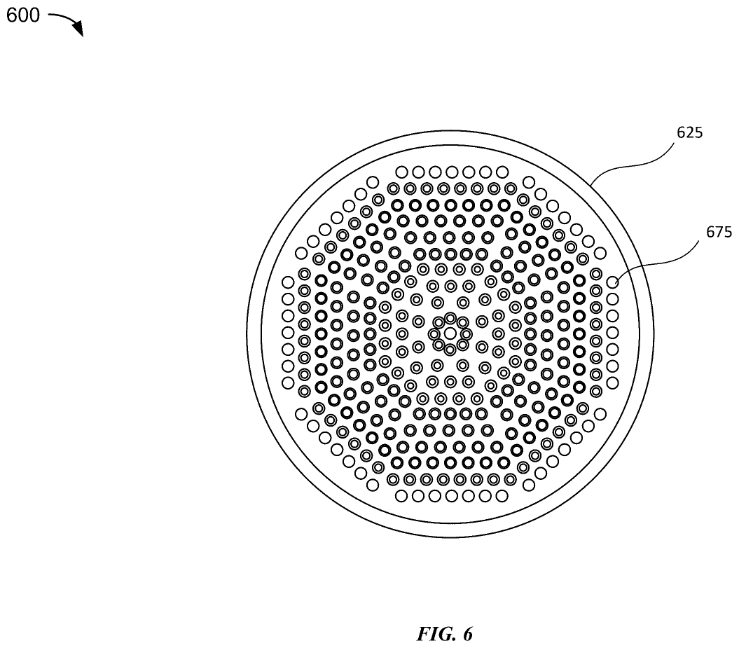

FIG. 6 illustrates a dual-channel showerhead 600 including apertures 675 arranged in octagonal concentric rings, according to certain embodiments. The dual-channel showerhead 600 may include any of the features or characteristics of dual-channel showerheads 300 or 400 and may be incorporated in any chamber in which a dual-channel showerhead may be used, including any chamber previously described. The dual-channel showerhead may include a lower plate 625. The apertures 675 may be arranged in octagonal concentric rings about a center of the dual-channel showerhead 600. Any number of octagonal concentric rings may be present (e.g., 10, 15, 20, etc.). Each of octagonal concentric rings may be included in a zone. Each zone may include one or more of the octagonal concentric rings. Each zone may be defined, at least in part, by a diameter of the apertures 675 included in each zone. For example, the apertures included in a zone nearer the center may include a diameter larger than those farther from the center, as is described in relation to FIGS. 4A and 4B.

Although FIGS. 5 and 6 illustrate two possible configurations of concentric rings, other possibilities and configurations are also possible. For example, the concentric rings may be substantially square, rectangular, triangular, or have any other such polygonal shape. The concentric rings may also be elliptical, and/or include straight and curved portions. Additionally or alternatively, the concentric rings may include a pattern (e.g., a star-pattern) One of ordinary skill in the art would recognize may different possibilities and configurations.

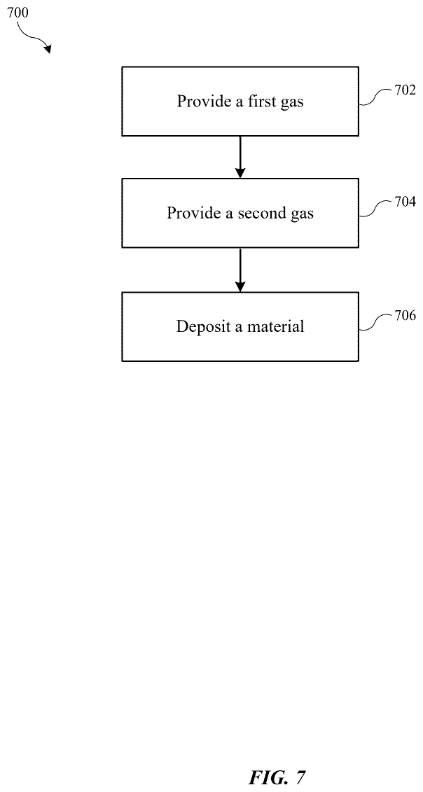

FIG. 7 illustrates a flowchart of a method 700 for processing a substrate, according to certain embodiments. The method 700 may be performed by some or all of the devices described herein, such as the dual-channel showerheads 300, 400, 500, and 600. Some of the steps in the method 700 may be performed out of the order shown, and or skipped altogether. At block 702, the method 700 may include providing a first gas into a processing chamber through a first subset of apertures of a showerhead. The showerhead may be similar to the dual-channel showerheads 300, 400, 500, and 600. The first subset of apertures may include apertures extending through an upper plate and lower plate of the showerhead, such as the first apertures 360 and second apertures 365 in FIG. 3. In some embodiments, each of the first subset of apertures may be fluidly connected to a gas line disposed in the showerhead. The gas line may provide the first gas to each of the first subset of apertures. The gas may be an oxygen-containing material. The gas may also include an inert gas such as Argon.

At block 704, the method may include providing a second gas into the processing chamber through a second subset of apertures. The second subset of apertures may be similar to the third apertures 475a-c in FIGS. 4A and B. The second subset of apertures may be fluidly connected to a gas inlet (e.g., the gas inlet assembly 205 in FIG. 2), via a channel and/or plenum (e.g., the plenum 347 in FIG. 3) formed in the showerhead. A flow conductance of the gas inlet may be equal to a total flow conductance of the second subset of apertures. In some embodiments, the second subset of apertures may be further divided into zones. The second subset of apertures may form one or more concentric rings about the center of the showerhead, as is shown in FIGS. 5 and 6. Each zone may include one or more of the concentric rings. The flow conductance of each of the zones may be substantially equal (e.g., within 5%). In some embodiments, each of the second subset of apertures may include a diameter dependent on a respective location of a respective aperture. The diameter may be within a range of 10 mm to 60 mm, inclusive.

The second gas may be similar to the precursor, described above (e.g., BDEAS). The saturation of the second gas may allow for deposition of a material on a substrate. For example, saturation may indicate a mole fraction of the second gas (as measured by a volume of total gas within the processing chamber is above a certain point). Because the flow conductance of each of the zones is substantially equal, some or all areas of the substrate may experience saturation at about the same time. Therefore, deposition may occur at a roughly equal rate at some or all areas of the substrate. In some embodiments, the saturation of the second gas may be reached within a range of 0.1 to 0.4 seconds, inclusive. A radial uniformity associated with the saturation may also be reached within a range of 0.1 to 0.4 seconds, inclusive.

At step 706, the method 700 may include depositing a material on a substrate positioned within the processing chamber. The material may be deposited as part of a semiconductor fabrication process. The material may form a layer and/or film on the material. The semiconductor fabrication process may include ALD, chemical deposition, or other such semiconductor processing techniques.

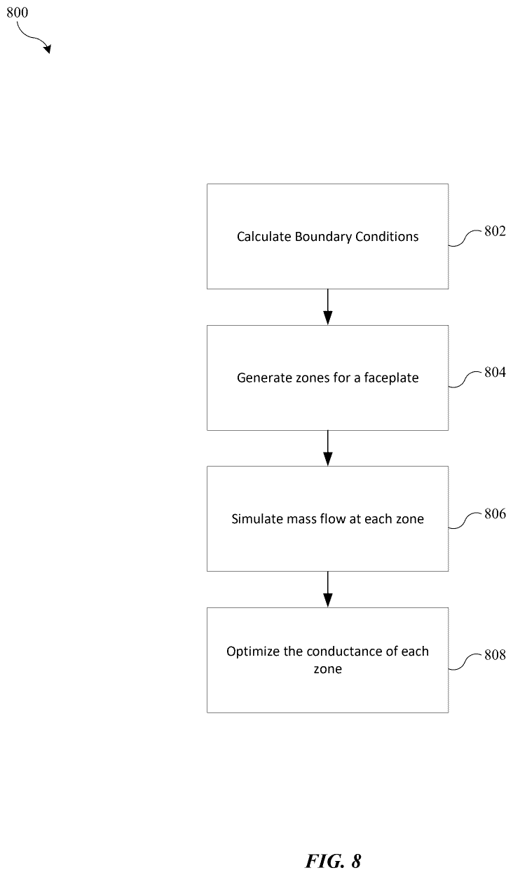

FIG. 8 illustrates a flowchart of a method 800 for optimizing flow conductance through a dual-channel showerhead, according to certain embodiments. The method 800 may be performed for some or all of the systems and devices described herein, such as the dual-channel showerhead 400 in FIG. 4. The method 800 may be performed in conjunction with the method 700. Some of the steps of the method 800 may be performed in a different order than is described herein, or combined with other steps. Some steps may be skipped altogether.

At step 802, the method 800 includes setting boundary conditions for a dual-channel shower head. The boundary conditions may include a flow rate of a precursor (e.g., BDEAS), a flow rate of a neutral gas (e.g., argon), a process volume pressure associated with a deposition process, and other such conditions.

At step 804, the method 800 may include generating one or more zones for a faceplate of a dual-channel showerhead. The one or more zones may each include a respective subset of apertures, characterized by a common diameter, such as the zones 1-3 in FIGS. 4A and 4B. Any number of zones may be generated (e.g., 3, 5, 10, etc.).

At step 806, the method 800 may include simulating a mass flow of the precursor at each zone. The simulation may be based on factors such as a molecular weight of the precursor, a volume of precursor delivered, a number of apertures in each zone, and other such factors. The simulation may also include predicted diameters for each aperture in each zone.

At step 808, the method 800 may include optimizing the conductance of each zone such that the mass flow rate of each zone is substantially equal (e.g., within 5%). For example, as zones nearer the edge may include more apertures than zones nearer to a center of the faceplate. Thus, optimization may include determining a larger diameter for the apertures nearest the edge than those in a zone nearer the center. To optimize the conductance, a difference between the zones at the edge and the zones nearer the center may be compared. The diameter of the apertures within each zone may then be adjusted such that conductance of each zone is substantially equal. Optimizing the conductance may be performed, at least in part, using nonlinear prediction (e.g., via a generalized reduced gradient method).

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A dual-channel showerhead, comprising:
a first plate defining two or more channels; and
a second plate comprising a bottom surface and defining a plurality of apertures, wherein:
each of the two or more channels is fluidly coupled with at least one of the plurality of apertures to define a fluid path extending from the first plate of the showerhead through the bottom surface of the showerhead and the plurality of apertures is arranged in a series of concentric rings about a center of the bottom surface, the plurality of apertures further comprising:
a first subset of apertures of the plurality of apertures, wherein each aperture of the first subset of apertures extends through the first plate and the bottom surface; and
a second subset of apertures of the plurality of apertures, wherein each aperture of the second subset of apertures in a first concentric ring of the series of concentric rings has a first opening area, and each aperture of the second subset of apertures in a second concentric ring has a second opening area smaller than the first opening area, such that a flow conductance of the first concentric ring is within 5% of the second concentric ring, and wherein the second concentric ring is radially outward of the first concentric ring.

2. The dual-channel showerhead of claim 1, wherein each ring within the series of concentric rings is arranged substantially hexagonally.

3. The dual-channel showerhead of claim 1, wherein each ring within the series of concentric rings is arranged substantially annularly.

4. The dual-channel showerhead of claim 1, wherein the first plate defines a recess and the second plate is disposed within the recess.

5. The dual-channel showerhead of claim 1, wherein a gas inlet comprises an opening formed on a lateral surface of the first plate.

6. The dual-channel showerhead of claim 5, wherein the second plate defines a plenum that fluidly couples the gas inlet with each aperture of the second subset of apertures.

7. The dual-channel showerhead of claim 6, wherein a total opening area of the second subset of apertures is substantially equal to an area of an inlet.

8. The dual-channel showerhead of claim 1, wherein a diameter of each aperture of the second subset of apertures decreases as a distance from the center of the bottom surface increases.

9. The dual-channel showerhead of claim 1, wherein a diameter of each of the second subset of apertures are within a range of 10 mm to 40 mm, inclusive.

10. The dual-channel showerhead of claim 1, wherein a total opening area of each concentric ring of apertures is defined by a total of the opening areas of each of the second subset of apertures within the respective concentric ring, and wherein the total opening area of each respective concentric ring is substantially equal.

11. The dual-channel showerhead of claim 1, each of the first subset of apertures and each of the second subset of apertures are generally cylindrical.

12. The dual-channel showerhead of claim 1, wherein each aperture of the plurality of apertures comprises a square shape.

13. The dual-channel showerhead of claim 1 wherein the first subset of apertures comprises a uniform diameter.

14. A semiconductor processing system comprising:
a processing chamber; and
a dual-channel showerhead within the processing chamber, further comprising:
a first plate defining two or more channels; and
a second plate comprising a bottom surface defining a plurality of apertures, wherein:
each of the two or more channels is fluidly coupled with at least one of the plurality of apertures to define a fluid path extending from the first plate of the dual-channel showerhead through the bottom surface of the dual-channel showerhead; and
the plurality of apertures is arranged in a series of concentric rings about a center of the bottom surface, the plurality of apertures further comprising:
a first subset of apertures of the plurality of apertures, wherein each aperture of the first subset of apertures extends through the first plate and the bottom surface; and
a second subset of apertures of the plurality of apertures, wherein each aperture of the second subset of apertures in a first concentric ring of the series of concentric rings has a first opening area, and each aperture of the second subset of apertures in a second concentric ring has a second opening area smaller than the first opening area, such that a flow conductance of the first concentric ring is within 5% of the second concentric ring, and wherein the second concentric ring is radially outward of the first concentric ring.

15. A method of processing a substrate, comprising:
providing a first gas into a processing chamber through a first subset of apertures of a showerhead;
providing a second gas into the processing chamber through a second subset of apertures of the showerhead, the second subset of apertures being fluidly connected to a gas inlet via at least one of a channel or a plenum formed in the showerhead, wherein a flow conductance of the gas inlet is the same as the flow conductance of the second subset of apertures; and
depositing a material on a substrate positioned within the processing chamber.

16. The method of claim 15, wherein the first gas comprises oxygen and the second gas comprises bis(diethylamino)silane.

17. The method of claim 15, wherein a saturation of at least the second gas in the processing chamber is reached within a range of 0.1 to 0.4 seconds, inclusive.

18. The method of claim 17, wherein a radial uniformity associated with the saturation is reached within a range of 0.1 to 0.4 seconds, inclusive.

19. The method of claim 15, wherein a diameter of each of the second subset of apertures are within a range of 10 mm to 60 mm, inclusive.

20. The method of claim 15, wherein each of the first subset of apertures is fluidly connected to a first gas line.
